(19) United States
(12) Patent Application Publication
(10) Pub. No.: US 2025/0067807 A1
(43) Pub. Date: Feb. 27, 2025

(54) FORMATION CAPACITY-GRADING APPARATUS AND PROBE SET DETECTION METHOD

(71) Applicant: ZHEJIANG JINKO ENERGY STORAGE CO., LTD., Haining City (CN)

(72) Inventors: Can CHEN, Haining City (CN); Yujun MA, Haining City (CN)

(21) Appl. No.: 18/949,503

(22) Filed: Nov. 15, 2024

(30) Foreign Application Priority Data
Sep. 23, 2024 (CN) 202411329553.1

(51) Int. Cl. G01R 31/36; G01R 31/387

(52) U.S. Cl. CPC G01R 31/3644; G01R 31/387

(57) ABSTRACT

The present disclosure provides a formation capacity-grading apparatus and a probe set detection method. The apparatus includes: a probe assembly including a plurality of connected probe sets, the probe sets being detachable, and the probe sets being configured to form and grade a capacity of a battery; a support apparatus located on one side of the probe assembly and configured to support the probe assembly and replace the probe sets; and a pressing platform with a height adjustable in a direction in which the probe assembly points to the support apparatus.

### CROSS-REFERENCE TO RELATED APPLICATIONS

This application claims priority to Chinese Patent Application No. 2024113295531, filed on Sep. 23, 2024, entitled “FORMATION CAPACITY-GRADING APPARATUS AND PROBE SET DETECTION METHOD”, the content of which is hereby incorporated by reference in its entirety.

### TECHNICAL FIELD

The present disclosure relates to the field of lithium-ion battery formation capacity-grading testing device technologies, and in particular, to a formation capacity-grading apparatus and a probe set detection method.

### BACKGROUND

During manufacturing of lithium-ion batteries in the prior art, a formation capacity-grading device mainly activates and charges and discharges a battery, and mainly contacts positive and negative posts of the battery through test probes, which lead out a contact resistance during the contact. Currently, the value of the contact resistance cannot be calculated by using conventional testing methods, and poor contact resistance, such as current fluctuations, voltage fluctuations, falsely high voltages, other undesirable features, can be identified only by relying on manual data analysis. At the same time, misjudgment may occur, because such undesirable features are not necessarily caused by the contact resistance during actual manufacturing, but may be caused by the battery, a lower machine board, and other factors.

Currently, the contact resistance of the conventional formation capacity-grading device does not have a sampling function, a contact state of the battery posts is not detected, and there is no closed-loop control. After the test probe has poor contact with the battery posts, there is a need to analyze data before disassembly and replacement of the test probe with a new one to prevent a defective battery. A normal process is to first shut down the entire apparatus, then disassemble a probe module through cooperation of multiple people, replace the probe with a new one, and then remount the probe module. The entire mounting and disassembly process requires the entire device to be shut down, and logistics line may also stop running in this case, affecting operating efficiency of the device.

### SUMMARY

The present disclosure provides a formation capacity-grading apparatus and a probe set detection method to solve the problem of poor operating efficiency of the formation capacity-grading apparatus due to the need to shut down the entire apparatus for replacement when the probe of the formation capacity-grading apparatus is replaced in the related art.

According to one aspect of the present disclosure, a formation capacity-grading apparatus is provided, including: a probe assembly including a plurality of connected probe sets, the plurality of probe sets are detachably connected and are configured to form and grade a capacity of a battery; a support apparatus located on one side of the probe assembly and configured to support the probe assembly and replace the plurality of probe sets; and a pressing platform, a height of the pressing platform is adjustable in a direction in which the probe assembly points towards the support apparatus.

Optionally, the support apparatus includes a first moving assembly, the first moving assembly including: an adjustment assembly, a connecting portion, and a plurality of second telescopic apparatuses, wherein one end of the connecting portion is connected to the adjustment assembly, two ends of the connecting portion in a preset direction are respectively connected to one ends of the second telescopic apparatuses, the other ends of the second telescopic apparatuses point towards the probe assembly, the adjustment assembly is configured to drive the connecting portion to make the second telescopic apparatus telescopic, and the preset direction is a length direction of the probe assembly.

Optionally, the formation capacity-grading apparatus further includes at least one probe module, the probe module being connected to the probe assembly, the probe sets are distributed in a row along a preset direction in the probe module, one end of the probe module in the preset direction is connected to the probe assembly through a buckle structure, the preset direction is the length direction of the probe assembly, and the adjustment assembly is further configured to open the buckle structure.

Optionally, the support apparatus further includes a second moving assembly, the second moving assembly including: a plurality of fixing assemblies, a first guide rail, and a plurality of rotatable assemblies, wherein the fixing assemblies are movably arranged on the first guide rail, the fixing assemblies are connected to the rotatable assemblies, and the rotatable assemblies are in one-to-one correspondence to the fixing assemblies; and the support apparatus further includes a first substrate and a second substrate, wherein the first substrate is located on one side of the first guide rail and is configured to fix the first guide rail, and two ends of the first substrate in the preset direction are connected to the rotatable assemblies; and the second substrate is located on a side of the first guide rail away from the first substrate, and two ends of the second substrate in the preset direction are connected to the rotatable assemblies.

Optionally, the rotatable assemblies include a first moving portion and a second moving portion, one end of the first moving portion is connected to an end of the first substrate in the preset direction, the other end of the first moving portion is connected to a center-of-gravity position of the second moving portion, and the second moving portion has one end connected to the fixing assemblies and the other end connected to an end of the second substrate in the preset direction.

Optionally, the support apparatus further includes a plurality of limiting structures, a second guide rail, and a support assembly, wherein the limiting structures are respectively located on the second substrate and at two ends of the second guide rail, the limiting structures are configured to limit the support assembly, and the support assembly is located on the second guide rail.

Optionally, each of the probe sets includes two probes, each of the probes has a current probe and a voltage probe, the current probe includes a current sampling line and a first voltage sampling line, the voltage probe is configured to detect a voltage of the battery, the current sampling line is configured to detect a current of the battery, and the first voltage sampling line is configured to detect a tab voltage of the battery.

Optionally, the formation capacity-grading apparatus further includes a plurality of power detection modules, the power detection modules being electrically connected to the first voltage sampling lines, the current sampling lines, and the voltage probes of the probe sets, and the power detection modules are in one-to-one correspondence to the probe sets.

According to another aspect of the present disclosure, a probe set detection method is provided, applied to the formation capacity-grading apparatus, wherein the detection method includes: an acquisition step: acquiring a contact resistance value between the probe of the formation capacity-grading apparatus and the battery; and a determination step: determining whether the contact resistance value is less than or equal to a resistance threshold, and sending an early warning signal when it is determined that the contact resistance value is greater than the resistance threshold,, the early warning signal is used to represent that the probe set is abnormal; and when it is determined that the contact resistance value is less than or equal to the resistance threshold, repeating the acquisition step and the determination step at least once after a preset period of time until the contact resistance value is greater than the resistance threshold.

Optionally, a battery detection module of the formation capacity-grading apparatus is electrically connected to a first voltage sampling line, a current sampling line, and a voltage probe of a probe set of the formation capacity-grading apparatus, and acquiring the contact resistance value between the probe of the formation capacity-grading apparatus and the battery includes: acquiring a voltage and a current of a battery and a tab voltage of the battery that are detected by the probe set, the tab voltage is collected by the battery detection module through the first voltage sampling line; obtaining a contact voltage between the probe and the battery according to the voltage and the tab voltage of the battery; and obtaining contact resistance between the probe and the battery according to the contact voltage and the current.

Through the technical solution of the present disclosure, a formation capacity-grading apparatus is provided, including a probe assembly, a support apparatus, and a pressing platform. The support apparatus is arranged on the pressing platform and is located on a side of the probe assembly adjacent to the pressing platform. When the probe set is detached, the support apparatus is adjusted to support the probe assembly, during the adjustment, one side of the probe set may be automatically separated from the probe assembly, and then a rear safety door of the formation capacity-grading apparatus is opened to separate the other side of the probe set from the probe assembly, so that the probe set can be detached and replaced on the support apparatus. Since a front safety door of the formation capacity-grading apparatus is not opened during the above process, a stacker at the front safety door of the formation capacity-grading apparatus can continue to operate without shutting down the entire apparatus. Therefore, the problem of poor operating efficiency of the formation capacity-grading apparatus due to the need to shut down the entire apparatus for replacement when the probe of the formation capacity-grading apparatus is replaced in the related art is solved.

### BRIEF DESCRIPTION OF THE DRAWINGS

The accompanying drawings forming part of the present disclosure are intended to provide further understanding of the present disclosure. Exemplary embodiments of the present disclosure and descriptions thereof are intended to explain the present disclosure, and do not constitute any inappropriate limitation on the present disclosure. In the accompanying drawings:

FIG. 1 is a partial schematic view of a formation capacity-grading apparatus according to embodiments of the present disclosure;

FIG. 2 is a schematic structural view of a probe module in a formation capacity-grading apparatus according to embodiments of the present disclosure;

FIG. 3 is a schematic structural view of a support apparatus in a formation capacity-grading apparatus according to embodiments of the present disclosure;

FIG. 4 is a schematic structural view of a support apparatus in another formation capacity-grading apparatus according to embodiments of the present disclosure;

FIG. 5 is a schematic structural view of a support apparatus in yet another formation capacity-grading apparatus according to embodiments of the present disclosure;

FIG. 6 is a schematic structural view of a probe module in still another formation capacity-grading apparatus according to embodiments of the present disclosure;

FIG. 7 is a schematic structural view of detection on a battery in a formation capacity-grading apparatus according to embodiments of the present disclosure;

FIG. 8 is a schematic view of a partial structure of another formation capacity-grading apparatus according to embodiments of the present disclosure; and

FIG. 9 is a schematic flowchart of a probe set detection method according to embodiments of the present disclosure.

The above drawings include the following reference signs:

10: probe assembly; 11: probe set; 12: probe; 13: current probe; 14: voltage probe; 15: current sampling line; 16: first voltage sampling line; 17: second voltage sampling line; 20: support apparatus; 201: adjustment assembly; 202: coupling; 203: handwheel; 204: connecting portion; 205: second telescopic apparatus; 206: fixed assembly; 207: first guide rail; 208: rotatable assembly; 209: first substrate; 210: second substrate; 211: first moving portion; 212: second moving portion; 213: limiting structure; 214: first limiting block; 215: second limiting block; 216: second guide rail; 217: support assembly; 218: positioning assembly; 30: pressing platform; 40: probe module; 41: fixed region; 42: hole; 50: power detection module; 60: battery; 70: cylinder; 80, guide post guide sleeve.

### DETAILED DESCRIPTION

It is to be noted that embodiments in the present disclosure and features in the embodiments may be combined with each other without conflict. The present disclosure will be described in detail below with reference to the accompanying drawings and embodiments.

In order to make those skilled in the art better understand the solutions of the present disclosure, the technical solutions in the embodiments of the present disclosure will be described clearly and completely below with reference to the accompanying drawings in the embodiments of the present disclosure. Apparently, the described embodiments are merely some of rather than all of the embodiments of the present disclosure. All other embodiments acquired by those of ordinary skill in the art without creative efforts based on the embodiments of the present disclosure shall fall within the protection scope of the present disclosure.

It is to be noted that the terms “first”, “second”, and the like in the specification and claims of the present disclosure and the accompanying drawings are used to distinguish similar objects and are not necessarily used to describe a specific order or sequence. It should be understood that data so used may be interchanged where appropriate, to facilitate the embodiments of the present disclosure described herein. In addition, The terms such as “comprise/include”, “have”, and any variants thereof are intended to cover a non-exclusive inclusion, for example, processes, methods, systems, products, or devices including a series of steps or units are not limited to these steps or units listed, and may include other steps or units not listed, or may include other steps or units inherent to these processes, methods, systems, products, or devices.

In the prior art, after the test probe has poor contact with the battery posts, there is a need to analyze data before disassembly and replacement of the test probe with a new one to prevent a defective battery. A normal process is to first shut down the entire formation capacity-grading apparatus, then disassemble a probe module through cooperation of multiple people, replace the probe with a new one, and then remount the probe module. The entire mounting and disassembly process requires the entire device to be shut down, and the logistics line may also stop running in this case, affecting operating efficiency of the device.

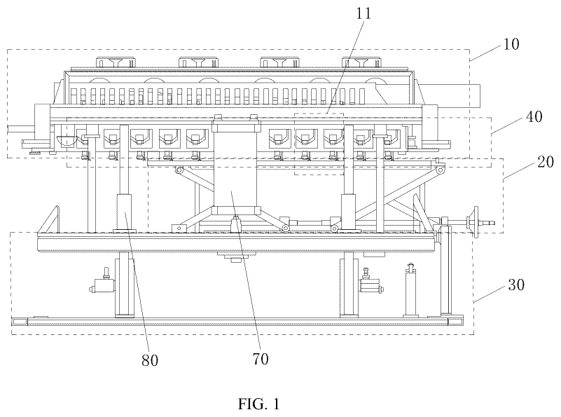

Therefore, research is conducted for the above issues. As shown in FIG. 1, embodiments of the present disclosure provide a formation capacity-grading apparatus, including: a probe assembly 10 including a plurality of connected probe sets 11, which are detachably connected, and the probe sets 11 are configured to form and grade a capacity of a battery; a support apparatus 20 located on one side of the probe assembly 10 and configured to support the probe assembly 10 and replace the probe sets 11; and a pressing platform 30 with an adjustable height in a direction in which the probe assembly 10 points towards the support apparatus 20.

When the probe set of the formation capacity-grading apparatus is detached, the support apparatus is adjusted to support the probe assembly. During the adjustment, one side of the probe set may be automatically separated from the probe assembly, and then a rear safety door of the formation capacity-grading apparatus is opened to separate the other side of the probe set from the probe assembly, so that the probe set can be detached and replaced on the support apparatus. Since a front safety door of the formation capacity-grading apparatus is not opened during the above process, a stacker at the front safety door of the formation capacity-grading apparatus can continue to operate without shutting down the entire apparatus. Therefore, the problem of poor operating efficiency of the formation capacity-grading apparatus due to the need to shut down the entire apparatus for replacement when the probe of the formation capacity-grading apparatus is replaced in the related art is solved.

In some optional embodiments, when it is found that the contact resistance value of one or more test probes in the plurality of probe sets exceeds a resistance threshold (such as 0.5 mΩ), an abnormal alarm will be triggered, indicating that the resistance value exceeds a scope. In this case, a process flow of the abnormal channel is immediately suspended, and manual intervention is performed to handle an abnormal test probe. For the first time, whether there is a foreign matter on the probe and post may be determined visually, and cleaning is performed first. If the contact resistance is still high after cleaning, a new probe is required for replacement. In this case, replacement is performed by using the support apparatus.

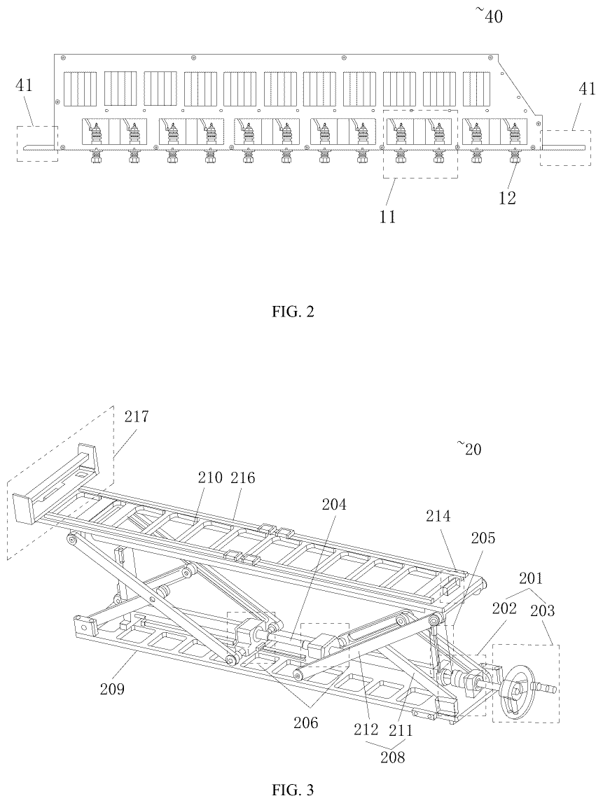

In some optional embodiments, as shown in FIG. 1 to FIG. 2, the formation capacity-grading apparatus further includes at least one probe module 40. The probe module 40 is connected to the probe assembly 10. The probe sets 11 are distributed in a row along a preset direction in the probe module 40. One end of the probe module 40 in the preset direction is connected to the probe assembly 10 through a buckle structure. The preset direction is the length direction of the probe assembly 10, and an adjustment assembly 201 is further configured to open the buckle structure.

In some optional embodiments, as shown in FIG. 1 to FIG. 2, the probe module 40 has fixed regions 41 at two ends. One fixed region 41 is connected and fixed to the probe assembly 10 through the buckle structure. The buckle structure may include a buckle and a hole in the fixed region 41. The probe module 40 includes a plurality of probe sets 11.

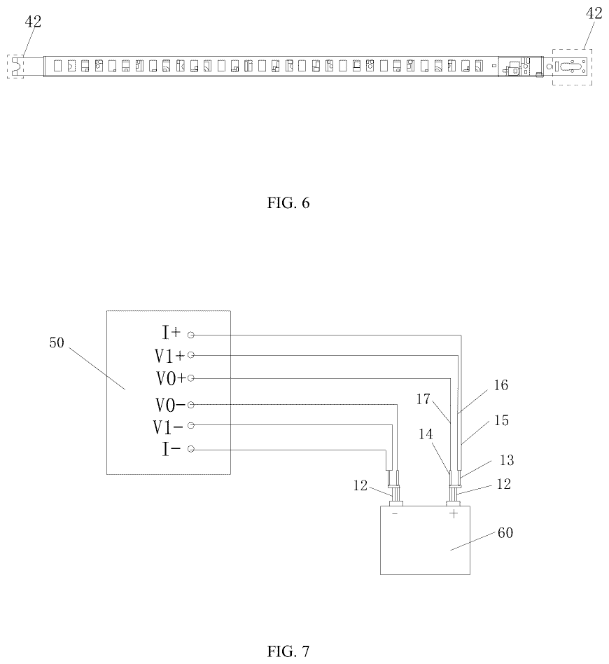

In some optional embodiments, as shown in FIG. 3 to FIG. 6, the support apparatus 20 includes a first moving assembly, and the first moving assembly includes: an adjustment assembly 201, a connecting portion 204, and a plurality of second telescopic apparatuses 205. One end of the connecting portion 204 is connected to the adjustment assembly 201, two ends of the connecting portion 204 in the preset direction are respectively connected to one ends of the second telescopic apparatuses 205, the other ends of the second telescopic apparatuses 205 point towards the probe assembly 10, the adjustment assembly 201 is configured to drive the connecting portion 204 to make the second telescopic apparatus 205 telescopic. The preset direction is a length direction of the probe assembly 10. As shown in FIG. 6, holes 42 are provided at the fixed regions, the hole 42 on the left is for fixing the buckle, and the hole 42 on the right is for fixing a screw. The hole 42 for fixing the buckle may be a semi-open hole, and the hole 42 for fixing the screw may be a semi-waist hole.

In some optional embodiments, as shown in FIG. 3 to FIG. 6, the adjustment assembly 201 may include a coupling 202 and a handwheel 203. By rotating the handwheel 203, the coupling 202 can drive the connecting portion 204 to drive the second telescopic apparatus 205, so as to lift or lower the support apparatus 20. During the rotation of the handwheel 203, the probe module 40 can be separated from the probe assembly 10. When the probe set 11 is replaced, the probe module 40 can be separated from the other end of the probe assembly 10 by only opening one safety door (rear safety door) of the formation capacity-grading apparatus without affecting overall operation of the formation capacity-grading apparatus.

In some optional embodiments, as shown in FIG. 3 to FIG. 6, the support apparatus 20 further includes a second moving assembly, and the second moving assembly includes: a plurality of fixing assemblies 206, a first guide rail 207, and a plurality of rotatable assemblies 208. The fixing assemblies 206 are movably arranged on the first guide rail 207, the fixing assemblies 206 are connected to the rotatable assemblies 208, and the rotatable assemblies 208 are in one-to-one correspondence to the fixing assemblies 206. The support apparatus 20 further includes a first substrate 209 and a second substrate 210. The first substrate 209 is located on one side of the first guide rail 207 and is configured to fix the first guide rail 207, and two ends of the first substrate 209 in the preset direction are connected to the rotatable assemblies 208. The second substrate 210 is located on a side of the first guide rail 207 away from the first substrate 209, and two ends of the second substrate 210 in the preset direction are connected to the rotatable assemblies 208.

In some optional embodiments, as shown in FIG. 3 to FIG. 5, the first guide rail 207 is arranged on the first substrate 209, the fixing assemblies 206 may be screw nuts, which are sleeved on the connecting portion 204, and connected to the first guide rail 207. The fixing assemblies 206 can slide on the first guide rail 207 and drive the rotatable assemblies 208 to move left and right during the sliding.

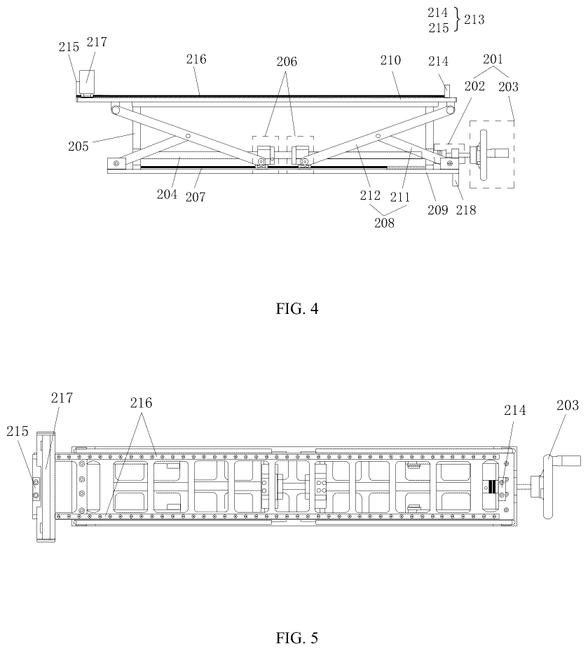

In some optional embodiments, as shown in FIG. 3 to FIG. 4, the rotatable assemblies 208 include a first moving portion 211 and a second moving portion 212. One end of the first moving portion 211 is connected to an end of the first substrate 209 in the preset direction, the other end of the first moving portion 211 is connected to a center-of-gravity position of the second moving portion 212. One end of the second moving portion 212 is connected to the fixing assemblies 206, and the other end of the second moving portion 212 is connected to an end of the second substrate 210 in the preset direction.

In some optional embodiments, as shown in FIG. 3 to FIG. 4, the first moving portion 211 and the second moving portion 212 are connected through a combination of a rotation pin and a bearing. The rotatable assemblies 208 and the second substrate 210 cooperatively support the probe assembly 10.

In some optional embodiments, as shown in FIG. 3 to FIG. 5, the support apparatus 20 further includes a plurality of limiting structures 213, a second guide rail 216, and a support assembly 217. The limiting structures 213 are respectively located on the second substrate 210 and at two ends of the second guide rail 216, and the limiting structures 213 are configured to limit the support assembly 217. The support assembly 217 is located on the second guide rail 216.

In some optional embodiments, as shown in FIG. 3 to FIG. 5, the limiting structure 213 includes a first limiting block 214 and a second limiting block 215, and the first limiting block 214 and the second limiting block 215 are located at two ends of the second guide rail 216, respectively. When the support assembly 217 slides on the second guide rail 216, the first limiting block 214 and the second limiting block 215 can limit the support assembly 217 and prevent the support assembly 217 from detaching from the second guide rail 216. The support apparatus 20 further includes a positioning assembly 218, a surface of the pressing platform 30 includes a ferromagnetic material positioning region, and the positioning assembly 218 is magnetically fixed to the positioning region, so that the support apparatus 20 can be fixed to the pressing platform 30.

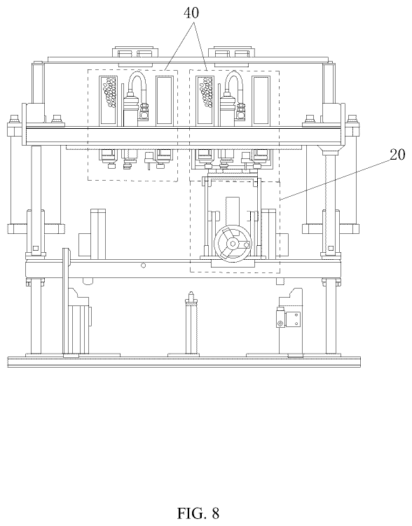

In some optional embodiments, as shown in FIG. 2 and FIG. 7, each probe set 11 includes two probes 12, each probe 12 has a current probe 13 and a voltage probe 14. The current probe 13 includes a current sampling line 15 and a first voltage sampling line 16, the voltage probe 14 is configured to detect a voltage of the battery 60, the current sampling line 15 is configured to detect a current of the battery 60, and the first voltage sampling line 16 is configured to detect a tab voltage of the battery 60.

In some optional embodiments, as shown in FIG. 2 and FIG. 7, each probe set 11 is configured to detect a battery 60. One of the two probes 12 is configured to detect a positive electrode of the battery 60, and the other of the two probes 12 is configured to detect a negative electrode of the battery 60. Two lines are led out from the current probe 13 on each probe 12, one of the two lines is the current sampling line 15 and the other of which is the first voltage sampling line 16. A second voltage sampling line 17 is led out from the voltage probe 14. The current, the tab voltage, and a real voltage of the battery 60 are detected through the current sampling line 15, the first voltage sampling line 16, and the second voltage sampling line 17, respectively.

In some optional embodiments, as shown in FIG. 7, the formation capacity-grading apparatus further includes a plurality of power detection modules 50. The power detection modules 50 are electrically connected to the first voltage sampling lines 16, the current sampling lines 15, and the voltage probes 14, and the power detection modules 50 are in one-to-one correspondence to the probe sets 11.

In some optional embodiments, each probe set 11 corresponds to one power detection module 50, so as to detect each probe set 11 in parallel to find an abnormal probe set 11 in a timely manner, thereby improving the detection efficiency, and reducing a risk of defective batteries. As shown in FIG. 7, the power detection module 50 has six junctions, three of which is for detecting the positive electrode of the battery 60, and three of which is for detecting the negative electrode of the battery 60. Three junctions correspond to detection of a charge and discharge sampling current I, a tab voltage V1, and a real voltage V0 of the battery 60, respectively. A voltage collected by the second voltage sampling line 17 is processed by a differential circuit of the power detection module 50 to obtain a real voltage V0 of a battery. V0 is used for module voltage control and analog-to-digital conversion. A voltage collected by the first voltage sampling line 16 is processed by the differential circuit of the power detection module 50 to obtain a tab voltage V1. A current collected by the current sampling line 15 is processed by the differential circuit of the power detection module 50 to obtain a charge and discharge sampling current I of a battery.

In some optional embodiments, as shown in FIG. 1, the formation capacity-grading apparatus further includes a power apparatus. The power apparatus includes a cylinder 70 and a guide post guide sleeve 80 that are provided between the pressing platform 30 and the probe assembly 10. When the probe set 11 is to be detached, firstly, the pressing platform 30 is driven to disengage through the cylinder 70 and the guide post guide sleeve 80, then a battery tray on the pressing platform 30 is transferred to other storage locations, the rear safety door of the device is opened, the support apparatus 20 is placed in the device, a screw for fixing the other end of the probe set 11 to the probe assembly 10 is removed, a place where the probe set 11 is fixed to the probe assembly 10 through the buckle structure is opened by shaking the adjustment assembly 201, and then by adjusting a height of a quick-release apparatus, a test cable is removed, and the probe sets 11 are detached and replaced in sequence.

In some optional embodiments, as shown in FIG. 8, the formation capacity-grading apparatus may include a plurality of probe modules 40, and the support apparatus 20 can support the plurality of probe modules 40 when the probe sets 11 are replaced, thereby reducing the cost of manufacturing the support apparatus 20.

In some optional embodiments, when there are relatively few probe sets 11 in the formation capacity-grading apparatus, the first voltage sampling line 16, the second voltage sampling line 17, the current sampling line 15, and the power detection module 50 can be integrated into one detection module, and the detection module is connected to the probe sets 11. When the probe set 11 is detached, the probe set 11 and the detection module can be removed at the same time and be replaced with a new probe set with a detection module. There is no need to connect a detection line of the new probe set after the probe set is removed, which simplifies the process replacing the probe set 11 and saves time.

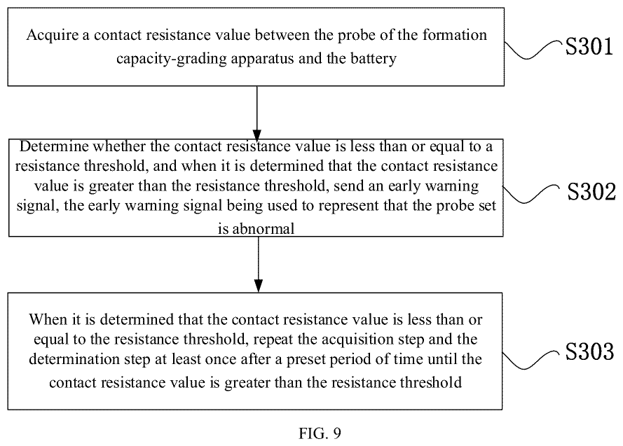

Embodiments of the present disclosure further provide a probe set detection method, applied to the aforementioned formation capacity-grading apparatus. As shown in FIG. 9, the detection method includes the following steps.

In an acquisition step S301, a contact resistance value between the probe of the formation capacity-grading apparatus and the battery is acquired.

In a determination step S302, whether the contact resistance value is less than or equal to a resistance threshold is determined, and when it is determined that the contact resistance value is greater than the resistance threshold, an early warning signal is sent. The early warning signal is used to represent that the probe set is abnormal.

In step S303, when it is determined that the contact resistance value is less than or equal to the resistance threshold, the acquisition step and the determination step are repeated at least once after a preset period of time, until the contact resistance value is greater than the resistance threshold.

According to the probe set detection method of the present disclosure, the contact resistance value between the probe of the formation capacity-grading apparatus and the battery is measured and acquired in real time, and the acquired contact resistance value is compared with the resistance threshold to determine magnitude of the current contact resistance value in real time. When the magnitude of the contact resistance value is not within a normal range, it indicates that the probe set is abnormal, and the entire test battery may be transferred to other storage locations of the formation capacity-grading apparatus of the device through a stacker, to continue process testing, which reduces the risk of defective batteries, and at the same time sends an early warning signal to a work platform to notify the staff to replace the probe, thereby improving operating efficiency of the formation capacity-grading apparatus.

In some optional embodiments, a battery detection module of the formation capacity-grading apparatus is electrically connected to a first voltage sampling line, a current sampling line, and a voltage probe of a probe set of the formation capacity-grading apparatus. The step of acquiring the contact resistance value between the probe of the formation capacity-grading apparatus and the battery includes: acquiring a voltage and a current of a battery and a tab voltage of the battery that are detected by the probe set, the tab voltage is collected by the battery detection module through the first voltage sampling line; obtaining a contact voltage between the probe and the battery according to the voltage and the tab voltage of the battery; and obtaining a contact resistance between the probe and the battery according to the contact voltage and the current.

In some optional embodiments, the real voltage of the battery is acquired according to the voltage probe and the battery detection module; the current of the battery is acquired according to the current sampling line and the battery detection module; the tab voltage of the battery is acquired according to the first voltage sampling line and the battery detection module; and the contact voltage value between the probe and the battery may be obtained according to the tab voltage, the real voltage, and a first formula. The first formula is V2=V1−V0. The contact resistance value between the probe and the battery may be obtained according to the contact voltage value, the current of the battery, and a second formula. The second formula is R=V2/I.

As can be seen from the above description, the embodiments of the present disclosure achieve the following technical effects.

1) Through the formation capacity-grading apparatus in the embodiments of the present disclosure, when the probe set is disassembled, the support apparatus is adjusted to support the probe assembly, during the adjustment, one side of the probe set may be automatically separated from the probe assembly, and then a rear safety door of the formation capacity-grading apparatus is opened to separate the other side of the probe set from the probe assembly, so that the probe set can be disassembled and replaced on the support apparatus. Since a front safety door of the formation capacity-grading apparatus is not opened in the above process, a stacker at the front safety door of the formation capacity-grading apparatus can continue to operate without shutting down the entire apparatus. Therefore, the problem of poor operating efficiency of the formation capacity-grading apparatus due to the need to shut down the entire apparatus for replacement when the probe of the formation capacity-grading apparatus is replaced in the related art is solved.

2) Through the probe set detection method in the embodiments of the present disclosure, the contact resistance value between the probe of the formation capacity-grading apparatus and the battery is measured and acquired in real time, the acquired contact resistance value is compared with the resistance threshold to determine magnitude of the current contact resistance value in real time, and when the magnitude of the contact resistance value is not within a normal range, it indicates that the probe set is abnormal, which reduces the risk of defective batteries, and at the same time sends an early warning signal to a work platform to notify the staff to replace the probe, thereby improving operating efficiency of the formation capacity-grading apparatus.

It is to be further noted that the terms such as “comprise”, “include”, or any other variants thereof are intended to cover a non-exclusive inclusion, so that a process, method, good, or device including a list of elements includes not only those elements but also other elements not expressly listed or that are inherent to the process, method, good, or device. Without more limitations, an element defined by the statement “including a/an . . . ” does not exclude the presence of additional identical elements in the process, method, good, or device that includes the element.

The above are merely embodiments of the present disclosure and are not intended to limit the present disclosure. For those skilled in the art, various modifications and changes may be made to the present disclosure. Any modifications, equivalent replacements, improvements, and the like made within the spirit and principles of the present disclosure shall be included in the scope of the claims of the present disclosure.

What is claimed is:

1. A formation capacity-grading apparatus, comprising:
a probe assembly comprising a plurality of probe sets, wherein the plurality of probe sets are detachably connected and are configured to form and grade a capacity of a battery;
a support apparatus located on one side of the probe assembly and configured to support the probe assembly and replace the plurality of probe sets; and
a pressing platform, wherein a height of the pressing platform is adjustable in a direction the probe assembly points towards the support apparatus.

2. The formation capacity-grading apparatus according to claim 1, wherein the support apparatus comprises a first moving assembly, the first moving assembly comprises: an adjustment assembly, a connecting portion, and a plurality of second telescopic apparatuses, wherein one end of the connecting portion is connected to the adjustment assembly, two ends of the connecting portion in a preset direction are respectively connected to ends of the second telescopic apparatuses, another ends of the second telescopic apparatuses point towards the probe assembly, the adjustment assembly is configured to drive the connecting portion to make the second telescopic apparatus telescopic, and the preset direction is a length direction of the probe assembly.

3. The formation capacity-grading apparatus according to claim 2, further comprising at least one probe module connected to the probe assembly, wherein the probe sets are distributed in a row along the preset direction in the probe module, one end of the probe module in the preset direction is connected to the probe assembly through a buckle structure, and the adjustment assembly is further configured to open the buckle structure.

4. The formation capacity-grading apparatus according to claim 2, wherein the support apparatus further comprises a second moving assembly, the second moving assembly comprises: a plurality of fixing assemblies, a first guide rail, and a plurality of rotatable assemblies, the fixing assemblies are movably arranged on the first guide rail, the fixing assemblies are connected to the rotatable assemblies, the rotatable assemblies are in one-to-one correspondence to the fixing assemblies; wherein the support apparatus further comprises a first substrate and a second substrate, the first substrate is located on one side of the first guide rail and is configured to fix the first guide rail, two ends of the first substrate in the preset direction are connected to the rotatable assemblies; the second substrate is located on a side of the first guide rail away from the first substrate, and two ends of the second substrate in the preset direction are connected to the rotatable assemblies.

5. The formation capacity-grading apparatus according to claim 4, wherein each rotatable assembly comprises a first moving portion and a second moving portion, one end of the first moving portion is connected to an end of the first substrate in the preset direction, another end of the first moving portion is connected to a center-of-gravity position of the second moving portion, one end of the second moving portion is connected to the fixing assemblies, and another end of the second moving portion is connected to an end of the second substrate in the preset direction.

6. The formation capacity-grading apparatus according to claim 4, wherein the support apparatus further comprises a plurality of limiting structures, a second guide rail, and a support assembly, the limiting structures are respectively located on the second substrate and at two ends of the second guide rail, the limiting structures are configured to limit the support assembly, and the support assembly is located on the second guide rail.

7. The formation capacity-grading apparatus according to claim 1, wherein each of the probe sets comprises two probes, each probe has a current probe and a voltage probe, the current probe comprises a current sampling line and a first voltage sampling line, the voltage probe is configured to detect a voltage of the battery, the current sampling line is configured to detect a current of the battery, and the first voltage sampling line is configured to detect a tab voltage of the battery.

8. The formation capacity-grading apparatus according to claim 7, further comprising a plurality of power detection modules electrically connected to the first voltage sampling lines, the current sampling lines, and the voltage probes of the probe sets, wherein the power detection modules are in one-to-one correspondence to the probe sets.

9. The formation capacity-grading apparatus according to claim 2, wherein the adjustment assembly comprises a coupling and a handwheel, by rotating the handwheel, the coupling drives the connecting portion to drive the second telescopic apparatus, so as to lift or lower the support apparatus.

10. The formation capacity-grading apparatus according to claim 4, wherein the first guide rail is arranged on the first substrate, the fixing assemblies are screw nuts sleeved on the connecting portion, and are connected to the first guide rail, the fixing assemblies slides on the first guide rail and drives the rotatable assemblies to move left and right during the sliding.

11. The formation capacity-grading apparatus according to claim 5, wherein the first moving portion and the second moving portion are connected through a combination of a rotation pin and a bearing, and the rotatable assemblies and the second substrate cooperatively support the probe assembly.

12. The formation capacity-grading apparatus according to claim 6, wherein the limiting structure comprises a first limiting block and a second limiting block that are located at two ends of the second guide rail, respectively, when the support assembly slides on the second guide rail, the first limiting block and the second limiting block limit the support assembly and prevent the support assembly from detaching from the second guide rail.

13. The formation capacity-grading apparatus according to claim 1, wherein the support apparatus further comprises a positioning assembly, a surface of the pressing platform comprises a ferromagnetic material positioning region, and the positioning assembly is magnetically fixed to the positioning region.

14. The formation capacity-grading apparatus according to claim 3, wherein the probe module has two fixed regions at two ends thereof, one fixed region is connected to the probe assembly through a buckle structure, and the buckle structure comprises a buckle and a hole in the fixed region.

15. The formation capacity-grading apparatus according to claim 7, wherein each probe set is configured to detect a battery, one of the two probes is configured to detect a positive electrode of the battery, and another of the two probes is configured to detect a negative electrode of the battery.

16. The formation capacity-grading apparatus according to claim 7, wherein a second voltage sampling line is led out from the voltage probe and is configured to detect a real voltage of the battery.

17. The formation capacity-grading apparatus according to claim 16, wherein the first voltage sampling line, the second voltage sampling line, the current sampling line, and the power detection module are integrated into a detection module, and the detection module is connected to the probe sets.

18. The formation capacity-grading apparatus according to claim 1, further comprising a power apparatus, wherein the power apparatus includes a cylinder and a guide post guide sleeve that are provided between the pressing platform and the probe assembly.

19. A probe set detection method applied to the formation capacity-grading apparatus according to claim 1, the method comprising:
an acquisition step: acquiring a contact resistance value between the probe of the formation capacity-grading apparatus and the battery;
a determination step: determining whether the contact resistance value is less than or equal to a resistance threshold; sending an early warning signal when it is determined that the contact resistance value is greater than the resistance threshold, wherein the early warning signal is used to represent that the probe set is abnormal; and
repeating the acquisition step and the determination step at least once after a preset period of time when it is determined that the contact resistance value is less than or equal to the resistance threshold until the contact resistance value is greater than the resistance threshold.

20. The method according to claim 19, wherein a battery detection module of the formation capacity-grading apparatus is electrically connected to a first voltage sampling line, a current sampling line, and a voltage probe of a probe set of the formation capacity-grading apparatus, and acquiring the contact resistance value between the probe of the formation capacity-grading apparatus and the battery comprises:
acquiring a voltage and a current of a battery and a tab voltage of the battery that are detected by the probe set, wherein the tab voltage is collected by the battery detection module through the first voltage sampling line;
obtaining a contact voltage between the probe and the battery according to the voltage and the tab voltage of the battery; and
obtaining a contact resistance between the probe and the battery according to the contact voltage and the current.
